(19) United States
(12) Patent Application Publication
(10) Pub. No.: US 2022/0217295 A1
(43) Pub. Date: Jul. 7, 2022

(54) IMAGE SUB-SAMPLING WITH A COLOR GRID ARRAY

(71) Applicant: Facebook Technologies, LLC, Menlo Park, CA (US)

(72) Inventors: Andrew Samuel Berkovich, Bellevue, WA (US); Shlomo Alkalay, Redmond, WA (US)

(21) Appl. No.: 17/645,904

(22) Filed: Dec. 23, 2021

Related U.S. Application Data
(60) Provisional application No. 63/133,899, filed on Jan. 5, 2021.

(51) Int. Cl. H04N 5/3745; H04N 5/378; H01L 27/146; G02B 27/01

(52) U.S. Cl. CPC H04N 5/37455; H04N 5/378; H04N 5/37452; G02B 2027/0178; H01L 27/14643; G02B 27/0172; H01L 27/14612; H01L 27/14621

(57) ABSTRACT

One example apparatus for image sub-sampling with a color grid array includes a super-pixel comprising an array of pixels, each pixel comprising a photodiode configured to generate a charge in response to incoming light, a filter positioned to filter the incoming light, a charge storage device to convert the charge to a voltage, a row-select switch, and a column-select switch; an analog-to-digital converter (“ADC”) connected to each of the charge storage devices of the super-pixel via the respective row-select and column-select switches and configured to selectively convert each respective stored voltage into a pixel value in response to a control signal; and wherein each row-select and column-select switch for a pixel is configured to selectively allow the charge or the voltage to propagate to the respective ADC, the row-select and column-select switches arranged in series.

### CROSS-REFERENCE TO RELATED APPLICATIONS

This application claims priority to U.S. Patent Application No. 63/133,899, titled “Method and System for Image Sub-Sampling with Color Grid Array,” filed Jan. 5, 2021, the entirety of which is hereby incorporated by reference.

### BACKGROUND

A typical image sensor includes an array of pixel cells. Each pixel cell may include a photodiode to sense light by converting photons into charge (e.g., electrons or holes). The charge generated by the array of photodiodes can then be quantized by an analog-to-digital converter (ADC) into digital values to generate a digital image. The digital image may be exported from the sensor to another system (e.g., a viewing system for viewing the digital image, a processing system for interpreting the digital image, a compilation system for compiling a set of digital images, etc.).

### SUMMARY

Various examples are described for image sub-sampling with a color grid array. One example sensor apparatus for image sub-sampling with a color grid array includes a super-pixel comprising an array of pixels, each pixel comprising a photodiode configured to generate a charge in response to incoming light, a filter positioned to filter the incoming light, a charge storage device to convert the charge to a voltage, a row-select switch, and a column-select switch; an analog-to-digital converter (“ADC”) connected to each of the charge storage devices of the super-pixel via the respective row-select and column-select switches and configured to selectively convert each respective stored voltage into a pixel value in response to a control signal; and wherein each row-select and column-select switch for a pixel is configured to selectively allow the charge or the voltage to propagate to the respective ADC, the row-select and column-select switches arranged in series.

In another aspect, each pixel has a different filter from the other pixels in the array. In a further aspect, the filters of the array of pixels include one or more of a red filter, a green filter, a blue filter, an infra-red filter, or an ultraviolet filter in the sensor apparatus.

In one aspect, the sensor apparatus includes a plurality of super-pixels arranged in an array. In another aspect, each super-pixel includes a 2×2 array of pixels in the sensor apparatus.

In another aspect, the sensor apparatus includes a pixel configuration controller configured to receive pixel control information for one or more super-pixels; selectively control row-select and column-select switches for each of the one or more super-pixels; and transmit the control signal to each of the super-pixels.

In another aspect, for each pixel, at least one of the row-select switch or column-select switch is connected between the photodiode and the charge storage device. In another aspect, for each pixel, at least one of the row-select switch or column-select switch is connected between the charge storage device and the ADC the sensor apparatus. In another aspect each pixel includes an anti-blooming transistor. In another aspect, the pixels are formed in a first layer of a semiconductor substrate and the ADC is formed in a second layer of the semiconductor substrate.

Another example sensor apparatus includes an array of super-pixels arranged in rows and columns, each super-pixel of the array of super-pixels comprising an array of pixels arranged in rows and columns and an analog-to-digital converter (ADC) connected to each pixel, each pixel comprising a photodiode configured to generate a charge in response to incoming light, a filter positioned to filter the incoming light, a charge storage device to convert the charge to a voltage, a row-select switch, and a column-select switch, wherein each row-select and column-select switch for a pixel is configured to selectively allow the charge or the voltage to propagate to the respective ADC, the row-select and column-select switches arranged in series; a plurality of row-select lines, each row-select line corresponding to a row of pixels within a row of super-pixels in the array of super-pixels, each row-select line connected to row-select switches of the pixels within the respective row of pixels; a plurality of column-select lines, each column-select line corresponding to a column of pixels within a column of super-pixels in the array of super-pixels, each column-select line connected to column-select switches of the pixels within the respective column of pixels; and a plurality of ADC enable lines, each ADC enable line configured to provide a control signal to enable at least one ADC.

In another aspect, each pixel array comprises four pixels arranged in a 2×2 array in the sensor apparatus. In a further aspect, a first filter of each pixel array comprises a red filter, a second filter of each pixel array comprises a green filter, and a third filter of each pixel array comprises a blue filter.

In another aspect, for each pixel, at least one of the row-select switch or column-select switch is connected between the photodiode and the charge storage device. In another aspect, for each pixel, at least one of the row-select switch or column-select switch is connected between the charge storage device and the respective ADC. In another aspect, the sensor aspect includes, for each pixel, an anti-blooming transistor. In another aspect, the pixels of each super-pixel are formed in a first layer of a semiconductor substrate and the ADC of each super-pixel is formed in a second layer of the semiconductor substrate.

An example method performed using a sensor apparatus including an array of super-pixels, each super-pixel comprising a plurality of pixels and being connected to an analog-to-digital converter (ADC), wherein each pixel for a super-pixel has a corresponding row-select switch and column-select switch, arranged in series, to allow a signal to propagate to the ADC when both switches are enabled, includes converting, by photodiodes of the pixels, incoming light in to electric charge; enabling a first row-select line, the first row-select line coupled to row-select switches in a first set of pixels in a first set of super-pixels of the array of super-pixels; enabling a first column-select line, the first column-select line coupled to column-select switches in a second set of pixels in a second set of super-pixels of the array of super-pixels; and generating, using the ADC corresponding to a super-pixel in both the first and second sets of super-pixels, a pixel value for each pixel of the respective super-pixel having both a row-select switch and column-select switch closed.

In another aspect, each super-pixel comprises four pixels arranged in a 2×2 pixel array, and wherein a first filter of each 2×2 pixel array comprises a red filter, a second filter of each 2×2 pixel array comprises a green filter, and a third filter of each 2×2 pixel array comprises a blue filter, and the method also includes enabling a plurality of row-select and column-select lines corresponding only to pixels having a first color filter.

In another aspect, each super-pixel comprises four pixels arranged in a 2×2 pixel array, and wherein a first filter of each 2×2 pixel array comprises a red filter, a second filter of each 2×2 pixel array comprises a green filter, and a third filter of each 2×2 pixel array comprises a blue filter, and the method also includes enabling a first plurality of row-select and column-select lines corresponding only to pixels having a red filter; enabling a first plurality of row-select and column-select lines corresponding only to pixels having a green filter; and enabling a first plurality of row-select and column-select lines corresponding only to pixels having a blue filter.

These illustrative examples are mentioned not to limit or define the scope of this disclosure, but rather to provide examples to aid understanding thereof. Illustrative examples are discussed in the Detailed Description, which provides further description. Advantages offered by various examples may be further understood by examining this specification.

### BRIEF DESCRIPTION OF THE DRAWINGS

The accompanying drawings, which are incorporated into and constitute a part of this specification, illustrate one or more certain examples and, together with the description of the example, serve to explain the principles and implementations of the certain examples.

FIG. 1A and FIG. 1B are diagrams of an embodiment of a near-eye display.

FIG. 2 is an embodiment of a cross section of the near-eye display.

FIG. 3 illustrates an isometric view of an embodiment of a wave guide display with a single source assembly.

FIG. 4 illustrates a cross section of an embodiment of the wave guide display.

FIG. 5 is a block diagram of an embodiment of a system including the near-eye display.

FIG. 6 illustrates an example of an imaging system that can perform image sub-sampling with a color grid array.

FIG. 7 illustrates an example of pixel array for image sub-sampling with a color grid array.

FIGS. 8-10 illustrate example super-pixels for image sub-sampling with a color grid array.

FIGS. 11A-11C illustrate an example pixel array that includes four super-pixels arranged in a 2×2 grid.

FIGS. 12-13 illustrate timing diagrams for image sub-sampling with a color grid array.

FIG. 14 illustrates an example method for image sub-sampling with a color grid array.

FIG. 15 illustrates an example of sparse image sensing using an example pixel array for image sub-sampling with a color grid array.

### DETAILED DESCRIPTION

Examples are described herein in the context of image sub-sampling with a color grid array. Those of ordinary skill in the art will realize that the following description is illustrative only and is not intended to be in any way limiting. Reference will now be made in detail to implementations of examples as illustrated in the accompanying drawings. The same reference indicators will be used throughout the drawings and the following description to refer to the same or like items.

In the interest of clarity, not all of the routine features of the examples described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another.

A typical image sensor includes an array of pixel cells. Each pixel cell includes a photodiode to sense incident light by converting photons into charge (e.g., electrons or holes). The charge generated by photodiodes of the array of pixel cells can then be quantized by an analog-to-digital converter (ADC) into digital values. The ADC can quantize the charge by, for example, using a comparator to compare a voltage representing the charge with one or more quantization levels, and a digital value can be generated based on the comparison result. The digital values can then be stored in a memory to generate a digital image.

The digital image data can support various wearable applications, such as object recognition and tracking, location tracking, augmented reality (AR), virtual reality (VR), etc. These and other applications may utilize extraction techniques to extract, from a subset of pixels of the digital image, aspects of the digital image (i.e., light levels, scenery, semantic regions) and/or features of the digital image (i.e., objects and entities represented in the digital image). For example, an application can identify pixels of reflected structured light (e.g., dots), compare a pattern extracted from the pixels with the transmitted structured light, and perform depth computation based on the comparison.

The application can also identify 2D pixel data from the same pixel cells that provide the extracted pattern of structured light to perform fusion of 2D and 3D sensing. To perform object recognition and tracking, an application can also identify pixels of image features of the object, extract the image features from the pixels, and perform the recognition and tracking based on the extraction results. These applications are typically executed on a host processor, which can be electrically connected with the image sensor and receive the pixel data via interconnects. The host processor, the image sensor, and the interconnects can be part of a wearable device.

Contemporary digital image sensors are complex apparatuses that convert light into digital image data. Programmable or “smart” sensors are powerful digital image sensors that may use a controller or other processing unit to alter the manner in which digital image data is generated from an analog light signal. These smart sensors have the ability to alter the manner in which a larger digital image is generated at the individual pixel level.

Smart sensors can consume a great amount of energy to function. Sensor-based processes that affect the generation of digital pixel data at the pixel level require a high frequency of information to be transferred onto the sensor, off the sensor, and between components of the sensor. Power consumption is a troubling issue for smart sensors, which consume relatively high levels of power when performing tasks at an individual pixel level of granularity. For example, a smart sensor manipulating individual pixel values may consume power to receive a signal regarding a pixel map, determine an individual pixel value from the pixel map, capture an analog pixel value based on the individual pixel value, convert the analog pixel value to a digital pixel value, combine the digital pixel value with other digital pixel values, export the digital pixel values off of the smart sensor, etc. The power consumption for these processes is compounded with each individual pixel that may be captured by the smart sensor and exported off-sensor. For example, it is not uncommon for sensors to capture digital images composed of over two million pixels at least 30 times or more per second, and each pixel captured and exported consumes energy.

This disclosure relates to a smart sensor that employs groupings of “pixels” into “super-pixels” to provide configurable sub-sampling per super-pixel. Each super-pixel provides a shared analog-to-digital conversion (“ADC”) functionality to its constituent pixels. In addition, each of the pixels within a super-pixel may be individually selected for sampling. This configurability can enable the smart sensor to dynamically configure the sensor to selectively capture information only from the specific portions of the sensor of interest at a particular time or to combine information captured by adjacent super-pixels. It can further reduce sampling and ADC power consumption if fewer than all pixels within a super-pixel are sampled for a given frame.

In some scenarios, a device may only need limited image data from an image sensor. For example, only certain pixels may capture information of interest in an image frame, such as based on object detection and tracking. Or full color channel information may not be needed for certain computer vision (“CV”) functionality, such as object recognition, SLAM functionality (simultaneous localization and mapping), etc. Thus capturing full-resolution and full-color images at every frame may be unnecessary.

To enable a configurable image sensor that supports subsampling, while also reducing energy consumption and areal density of components within the sensor, an example image sensor includes an array of pixels that each have a light-sensing element, such as a photodiode, that is connected to a charge storage device. A super-pixel includes multiple pixels that have their charge storage devices connected to common analog-to-digital conversion (“ADC”) circuitry. To allow individual pixels to be selected for ADC operations, row-select and column-select switches are included for each pixel that can be selectively enabled or disabled to allow stored charge or voltage from the pixel to be transferred to the ADC circuitry for conversion.

During an exposure period, the each pixel's photodiode captures incoming light and converts it to an electric charge which is stored in the charge storage device, e.g., a floating diffusion (“FD”) region. During quantization, row and column select signals are transmitted to some (or all) of the pixels in the sensor to selectively connect individual pixels in a super pixel to the ADC circuitry for conversion to a digital value. However, because multiple pixels share the same ADC circuitry, multiple row and column select signals may be sent in sequence to select different pixels within the super-pixel for conversion within a single quantization period.

Thus, in operation, after the exposure period completes, quantization begins and a set of pixels are sampled by enabling a set of row and column select lines. The charge or voltage at the selected pixels are sampled and converted to pixel values, which are stored and then read-out. If additional pixels are to be sampled, additional sampling and conversion operations occur by enabling different sets of row and column select lines, followed by ADC, storage, and read-out operations. Once all pixels to be sampled have been sampled, the pixels are reset and the next exposure period begins.

Because each pixel can be individually addressed, only specific pixels of interest can be sampled. Thus, example image sensors can enable “sparse sensing,” where only pixels that capture light from an object of interest may be sampled, e.g., only pixels anticipated to capture light reflected by a ball in flight, while the remaining pixels are not sampled. In addition, because pixels are grouped into super-pixels, each pixel within a super-pixel can be configured with a different filter to capture different visible color bands (e.g., red, green, blue, yellow, white), different spectral bands (e.g., near-infrared (“IR”), monochrome, ultraviolet (“UV”), IR cut, IR band pass), or similar. Thus, for certain computer-vision (“CV”) functionality, full color information may not be needed, thus only one pixel per super-pixel may be sampled. Further, because ADC circuitry is shared by groups of pixels, the size and complexity of the image sensor can be reduced.

In another example, pixels from adjacent super-pixels can be sampled and combined to provide a downsampled image. For example, if each super-pixel includes a 2×2 array of pixels, with RGGB color filters, individual pixels from four adjoining super-pixels may be sampled to obtain a full-color pixel, but using only a single sampling and ADC operation per super-pixel, whereas capturing a full-resolution, full color image would require three or four sampling and ADC operations per super-pixel.

Thus, example image sensors according to this disclosure can provide highly configurable image capture with configurable per-pixel sub-sampling with reduced power consumption and complexity.

This illustrative example is given to introduce the reader to the general subject matter discussed herein and the disclosure is not limited to this example. The following sections describe various additional non-limiting examples and examples of image sub-sampling with a color grid array.

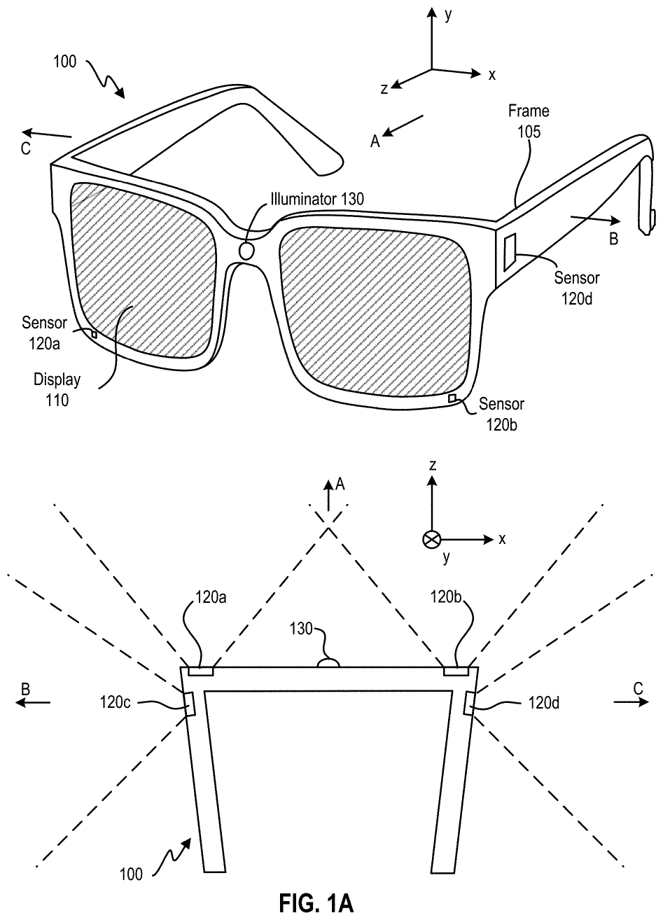

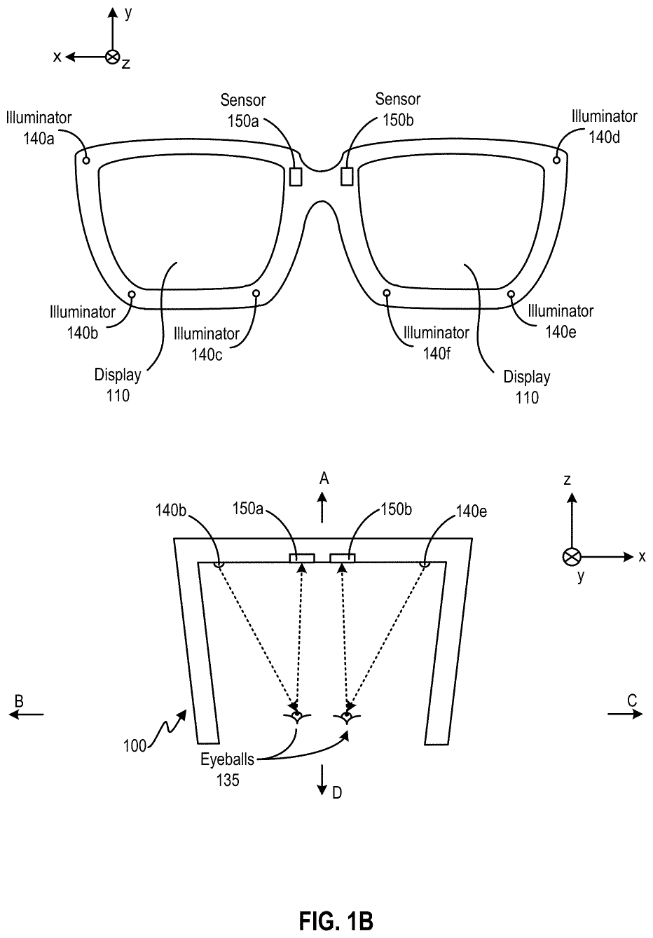

FIG. 1A is a diagram of an embodiment of a near-eye display 100. Near-eye display 100 presents media to a user. Examples of media presented by near-eye display 100 include one or more images, video, and/or audio. In some embodiments, audio is presented via an external device (e.g., speakers and/or headphones) that receives audio information from the near-eye display 100, a console, or both, and presents audio data based on the audio information. Near-eye display 100 is generally configured to operate as a virtual reality (VR) display. In some embodiments, near-eye display 100 is modified to operate as an augmented reality (AR) display and/or a mixed reality (MR) display.

Near-eye display 100 includes a frame 105 and a display 110. Frame 105 is coupled to one or more optical elements. Display 110 is configured for the user to see content presented by near-eye display 100. In some embodiments, display 110 comprises a wave guide display assembly for directing light from one or more images to an eye of the user.

Near-eye display 100 further includes image sensors 120a, 120b, 120c, and 120d. Each of image sensors 120a, 120b, 120c, and 120d may include a pixel array configured to generate image data representing different fields of views along different directions. For example, sensors 120a and 120b may be configured to provide image data representing two fields of view towards a direction A along the Z axis, whereas sensor 120c may be configured to provide image data representing a field of view towards a direction B along the X axis, and sensor 120d may be configured to provide image data representing a field of view towards a direction C along the X axis.

In some embodiments, sensors 120a-120d can be configured as input devices to control or influence the display content of the near-eye display 100 to provide an interactive VR/AR/MR experience to a user who wears near-eye display 100. For example, sensors 120a-120d can generate physical image data of a physical environment in which the user is located. The physical image data can be provided to a location tracking system to track a location and/or a path of movement of the user in the physical environment. A system can then update the image data provided to display 110 based on, for example, the location and orientation of the user, to provide the interactive experience. In some embodiments, the location tracking system may operate a SLAM algorithm to track a set of objects in the physical environment and within a view of field of the user as the user moves within the physical environment. The location tracking system can construct and update a map of the physical environment based on the set of objects, and track the location of the user within the map. By providing image data corresponding to multiple fields of views, sensors 120a-120d can provide the location tracking system a more holistic view of the physical environment, which can lead to more objects to be included in the construction and updating of the map. With such an arrangement, the accuracy and robustness of tracking a location of the user within the physical environment can be improved.

In some embodiments, near-eye display 100 may further include one or more active illuminators 130 to project light into the physical environment. The light projected can be associated with different frequency spectrums (e.g., visible light, infra-red light, ultra-violet light), and can serve various purposes. For example, illuminator 130 may project light in a dark environment (or in an environment with low intensity of infra-red light, ultra-violet light, etc.) to assist sensors 120a-120d in capturing images of different objects within the dark environment to, for example, enable location tracking of the user. Illuminator 130 may project certain markers onto the objects within the environment, to assist the location tracking system in identifying the objects for map construction/updating.

In some embodiments, illuminator 130 may also enable stereoscopic imaging. For example, one or more of sensors 120a or 120b can include both a first pixel array for visible light sensing and a second pixel array for infra-red (IR) light sensing. The first pixel array can be overlaid with a color filter (e.g., a Bayer filter), with each pixel of the first pixel array being configured to measure intensity of light associated with a particular color (e.g., one of red, green or blue colors). The second pixel array (for IR light sensing) can also be overlaid with a filter that allows only IR light through, with each pixel of the second pixel array being configured to measure intensity of IR lights. The pixel arrays can generate an RGB image and an IR image of an object, with each pixel of the IR image being mapped to each pixel of the RGB image. Illuminator 130 may project a set of IR markers on the object, the images of which can be captured by the IR pixel array. Based on a distribution of the IR markers of the object as shown in the image, the system can estimate a distance of different parts of the object from the IR pixel array, and generate a stereoscopic image of the object based on the distances. Based on the stereoscopic image of the object, the system can determine, for example, a relative position of the object with respect to the user, and can update the image data provided to display 100 based on the relative position information to provide the interactive experience.

As discussed above, near-eye display 100 may be operated in environments associated with a very wide range of light intensities. For example, near-eye display 100 may be operated in an indoor environment or in an outdoor environment, and/or at different times of the day. Near-eye display 100 may also operate with or without active illuminator 130 being turned on. As a result, image sensors 120a-120d may need to have a wide dynamic range to be able to operate properly (e.g., to generate an output that correlates with the intensity of incident light) across a very wide range of light intensities associated with different operating environments for near-eye display 100.

FIG. 1B is a diagram of another embodiment of near-eye display 100. FIG. 1B illustrates a side of near-eye display 100 that faces the eyeball(s) 135 of the user who wears near-eye display 100. As shown in FIG. 1B, near-eye display 100 may further include a plurality of illuminators 140a, 140b, 140c, 140d, 140e, and 140f. Near-eye display 100 further includes a plurality of image sensors 150a and 150b. Illuminators 140a, 140b, and 140c may emit lights of certain frequency range (e.g., NIR) towards direction D (which is opposite to direction A of FIG. 1A). The emitted light may be associated with a certain pattern, and can be reflected by the left eyeball of the user. Sensor 150a may include a pixel array to receive the reflected light and generate an image of the reflected pattern. Similarly, illuminators 140d, 140e, and 140f may emit NIR lights carrying the pattern. The NIR lights can be reflected by the right eyeball of the user, and may be received by sensor 150b. Sensor 150b may also include a pixel array to generate an image of the reflected pattern. Based on the images of the reflected pattern from sensors 150a and 150b, the system can determine a gaze point of the user, and update the image data provided to display 100 based on the determined gaze point to provide an interactive experience to the user.

As discussed above, to avoid damaging the eyeballs of the user, illuminators 140a, 140b, 140c, 140d, 140e, and 140f are typically configured to output lights of very low intensities. In a case where image sensors 150a and 150b comprise the same sensor devices as image sensors 120a-120d of FIG. 1A, the image sensors 120a-120d may need to be able to generate an output that correlates with the intensity of incident light when the intensity of the incident light is very low, which may further increase the dynamic range requirement of the image sensors.

Moreover, the image sensors 120a-120d may need to be able to generate an output at a high speed to track the movements of the eyeballs. For example, a user's eyeball can perform a very rapid movement (e.g., a saccade movement) in which there can be a quick jump from one eyeball position to another. To track the rapid movement of the user's eyeball, image sensors 120a-120d need to generate images of the eyeball at high speed. For example, the rate at which the image sensors generate an image frame (the frame rate) needs to at least match the speed of movement of the eyeball. The high frame rate requires short total exposure time for all of the pixel cells involved in generating the image frame, as well as high speed for converting the sensor outputs into digital values for image generation. Moreover, as discussed above, the image sensors also need to be able to operate at an environment with low light intensity.

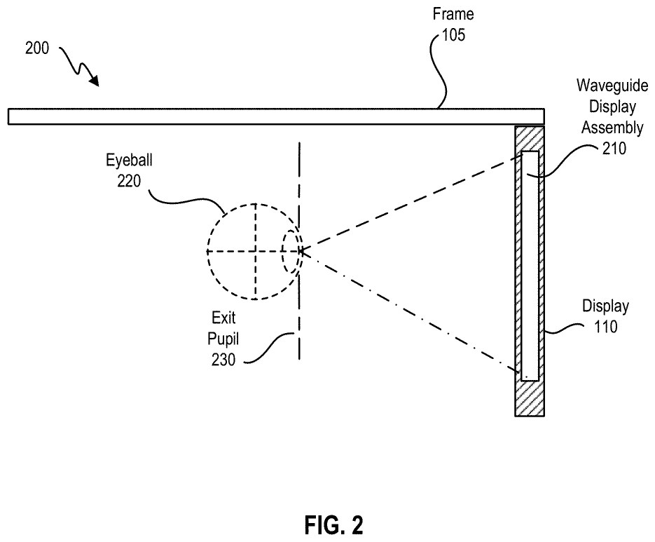

FIG. 2 is an embodiment of a cross section 200 of near-eye display 100 illustrated in FIG. 1. Display 110 includes at least one waveguide display assembly 210. An exit pupil 230 is a location where a single eyeball 220 of the user is positioned in an eyebox region when the user wears the near-eye display 100. For purposes of illustration, FIG. 2 shows the cross section 200 associated eyeball 220 and a single waveguide display assembly 210, but a second waveguide display is used for a second eye of a user.

Waveguide display assembly 210 is configured to direct image light to an eyebox located at exit pupil 230 and to eyeball 220. Waveguide display assembly 210 may be composed of one or more materials (e.g., plastic, glass) with one or more refractive indices. In some embodiments, near-eye display 100 includes one or more optical elements between waveguide display assembly 210 and eyeball 220.

In some embodiments, waveguide display assembly 210 includes a stack of one or more waveguide displays including, but not restricted to, a stacked waveguide display, a varifocal waveguide display, etc. The stacked waveguide display is a polychromatic display (e.g., a red-green-blue (RGB) display) created by stacking waveguide displays whose respective monochromatic sources are of different colors. The stacked waveguide display is also a polychromatic display that can be projected on multiple planes (e.g., multi-planar colored display). In some configurations, the stacked waveguide display is a monochromatic display that can be projected on multiple planes (e.g., multi-planar monochromatic display). The varifocal waveguide display is a display that can adjust a focal position of image light emitted from the waveguide display. In alternate embodiments, waveguide display assembly 210 may include the stacked waveguide display and the varifocal waveguide display.

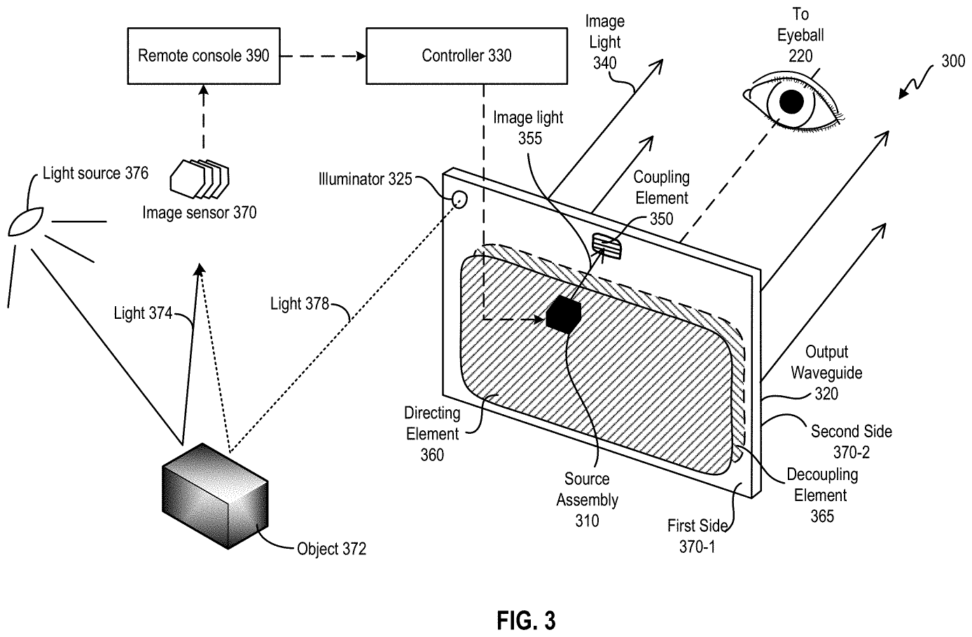

FIG. 3 illustrates an isometric view of an embodiment of a waveguide display 300. In some embodiments, waveguide display 300 is a component (e.g., waveguide display assembly 210) of near-eye display 100. In some embodiments, waveguide display 300 is part of some other near-eye display or other system that directs image light to a particular location.

Waveguide display 300 includes a source assembly 310, an output waveguide 320, and a controller 330. For purposes of illustration, FIG. 3 shows the waveguide display 300 associated with a single eyeball 220, but in some embodiments, another waveguide display separate, or partially separate, from the waveguide display 300 provides image light to another eye of the user.

Source assembly 310 generates and outputs image light 355 to a coupling element 350 located on a first side 370-1 of output waveguide 320. Output waveguide 320 is an optical waveguide that outputs expanded image light 340 to an eyeball 220 of a user. Output waveguide 320 receives image light 355 at one or more coupling elements 350 located on the first side 370-1 and guides received input image light 355 to a directing element 360. In some embodiments, coupling element 350 couples the image light 355 from source assembly 310 into output waveguide 320. Coupling element 350 may be, e.g., a diffraction grating, a holographic grating, one or more cascaded reflectors, one or more prismatic surface elements, and/or an array of holographic reflectors.

Directing element 360 redirects the received input image light 355 to decoupling element 365 such that the received input image light 355 is decoupled out of output waveguide 320 via decoupling element 365. Directing element 360 is part of, or affixed to, first side 370-1 of output waveguide 320. Decoupling element 365 is part of, or affixed to, second side 370-2 of output waveguide 320, such that directing element 360 is opposed to the decoupling element 365. Directing element 360 and/or decoupling element 365 may be, e.g., a diffraction grating, a holographic grating, one or more cascaded reflectors, one or more prismatic surface elements, and/or an array of holographic reflectors.

Second side 370-2 represents a plane along an x-dimension and a y-dimension. Output waveguide 320 may be composed of one or more materials that facilitate total internal reflection of image light 355. Output waveguide 320 may be composed of e.g., silicon, plastic, glass, and/or polymers. Output waveguide 320 has a relatively small form factor. For example, output waveguide 320 may be approximately 50 mm wide along x-dimension, 30 mm long along y-dimension and 0.5-1 mm thick along a z-dimension.

Controller 330 controls scanning operations of source assembly 310. The controller 330 determines scanning instructions for the source assembly 310. In some embodiments, the output waveguide 320 outputs expanded image light 340 to the user's eyeball 220 with a large field of view (FOV). For example, the expanded image light 340 is provided to the user's eyeball 220 with a diagonal FOV (in x and y) of 60 degrees and/or greater and/or 150 degrees and/or less. The output waveguide 320 is configured to provide an eyebox with a length of 20 mm or greater and/or equal to or less than 50 mm; and/or a width of 10 mm or greater and/or equal to or less than 50 mm.

Moreover, controller 330 also controls image light 355 generated by source assembly 310, based on image data provided by image sensor 370. Image sensor 370 may be located on first side 370-1 and may include, for example, image sensors 120a-120d of FIG. 1A. Image sensors 120a-120d can be operated to perform 2D sensing and 3D sensing of, for example, an object 372 in front of the user (e.g., facing first side 370-1). For 2D sensing, each pixel cell of image sensors 120a-120d can be operated to generate pixel data representing an intensity of light 374 generated by a light source 376 and reflected off object 372. For 3D sensing, each pixel cell of image sensors 120a-120d can be operated to generate pixel data representing a time-of-flight measurement for light 378 generated by illuminator 325. For example, each pixel cell of image sensors 120a-120d can determine a first time when illuminator 325 is enabled to project light 378 and a second time when the pixel cell detects light 378 reflected off object 372. The difference between the first time and the second time can indicate the time-of-flight of light 378 between image sensors 120a-120d and object 372, and the time-of-flight information can be used to determine a distance between image sensors 120a-120d and object 372. Image sensors 120a-120d can be operated to perform 2D and 3D sensing at different times, and provide the 2D and 3D image data to a remote console 390 that may be (or may not be) located within waveguide display 300. The remote console may combine the 2D and 3D images to, for example, generate a 3D model of the environment in which the user is located, to track a location and/or orientation of the user, etc. The remote console may determine the content of the images to be displayed to the user based on the information derived from the 2D and 3D images. The remote console can transmit instructions to controller 330 related to the determined content. Based on the instructions, controller 330 can control the generation and outputting of image light 355 by source assembly 310, to provide an interactive experience to the user.

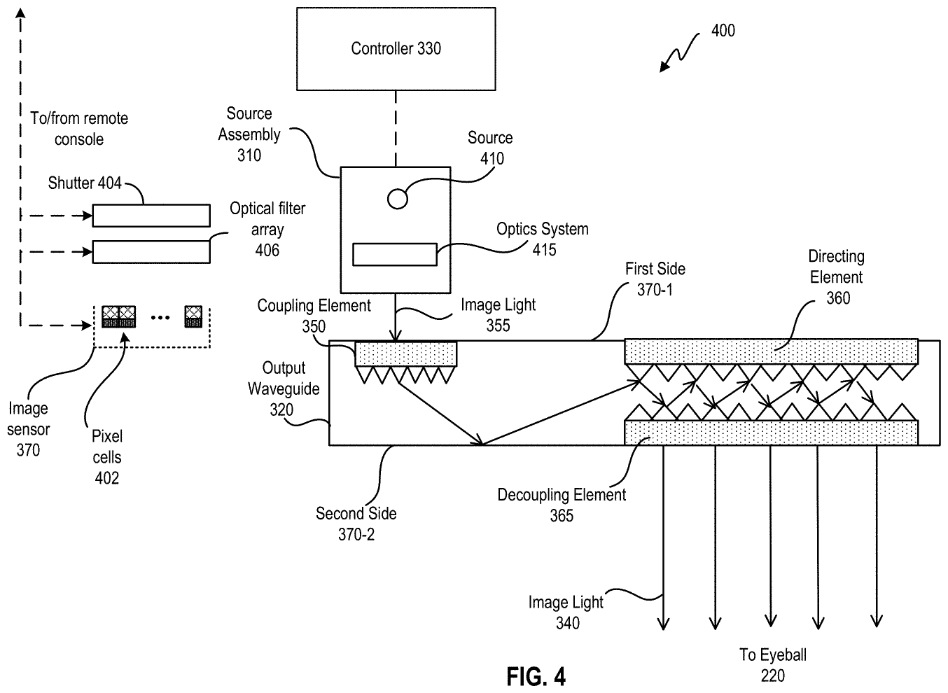

FIG. 4 illustrates an embodiment of a cross section 400 of the waveguide display 300. The cross section 400 includes source assembly 310, output waveguide 320, and image sensor 370. In the example of FIG. 4, image sensor 370 may include a set of pixel cells 402 located on first side 370-1 to generate an image of the physical environment in front of the user. In some embodiments, there can be a mechanical shutter 404 and an optical filter array 406 interposed between the set of pixel cells 402 and the physical environment. Mechanical shutter 404 can control the exposure of the set of pixel cells 402. In some embodiments, the mechanical shutter 404 can be replaced by an electronic shutter gate, as to be discussed below. Optical filter array 406 can control an optical wavelength range of light the set of pixel cells 402 is exposed to, as to be discussed below. Each of pixel cells 402 may correspond to one pixel of the image. Although not shown in FIG. 4, it is understood that each of pixel cells 402 may also be overlaid with a filter to control the optical wavelength range of the light to be sensed by the pixel cells.

After receiving instructions from the remote console, mechanical shutter 404 can open and expose the set of pixel cells 402 in an exposure period. During the exposure period, image sensor 370 can obtain samples of lights incident on the set of pixel cells 402, and generate image data based on an intensity distribution of the incident light samples detected by the set of pixel cells 402. Image sensor 370 can then provide the image data to the remote console, which determines the display content, and provide the display content information to controller 330. Controller 330 can then determine image light 355 based on the display content information.

Source assembly 310 generates image light 355 in accordance with instructions from the controller 330. Source assembly 310 includes a source 410 and an optics system 415. Source 410 is a light source that generates coherent or partially coherent light. Source 410 may be, e.g., a laser diode, a vertical cavity surface emitting laser, and/or a light emitting diode.

Optics system 415 includes one or more optical components that condition the light from source 410. Conditioning light from source 410 may include, e.g., expanding, collimating, and/or adjusting orientation in accordance with instructions from controller 330. The one or more optical components may include one or more lenses, liquid lenses, mirrors, apertures, and/or gratings. In some embodiments, optics system 415 includes a liquid lens with a plurality of electrodes that allows scanning of a beam of light with a threshold value of scanning angle to shift the beam of light to a region outside the liquid lens. Light emitted from the optics system 415 (and also source assembly 310) is referred to as image light 355.

Output waveguide 320 receives image light 355. Coupling element 350 couples image light 355 from source assembly 310 into output waveguide 320. In embodiments where coupling element 350 is a diffraction grating, a pitch of the diffraction grating is chosen such that total internal reflection occurs in output waveguide 320, and image light 355 propagates internally in output waveguide 320 (e.g., by total internal reflection), toward decoupling element 365.

Directing element 360 redirects image light 355 toward decoupling element 365 for decoupling from output waveguide 320. In embodiments where directing element 360 is a diffraction grating, the pitch of the diffraction grating is chosen to cause incident image light 355 to exit output waveguide 320 at angle(s) of inclination relative to a surface of decoupling element 365.

In some embodiments, directing element 360 and/or decoupling element 365 are structurally similar. Expanded image light 340 exiting output waveguide 320 is expanded along one or more dimensions (e.g., may be elongated along x-dimension). In some embodiments, waveguide display 300 includes a plurality of source assemblies 310 and a plurality of output waveguides 320. Each of source assemblies 310 emits a monochromatic image light of a specific band of wavelength corresponding to a primary color (e.g., red, green, or blue). Each of output waveguides 320 may be stacked together with a distance of separation to output an expanded image light 340 that is multi-colored.

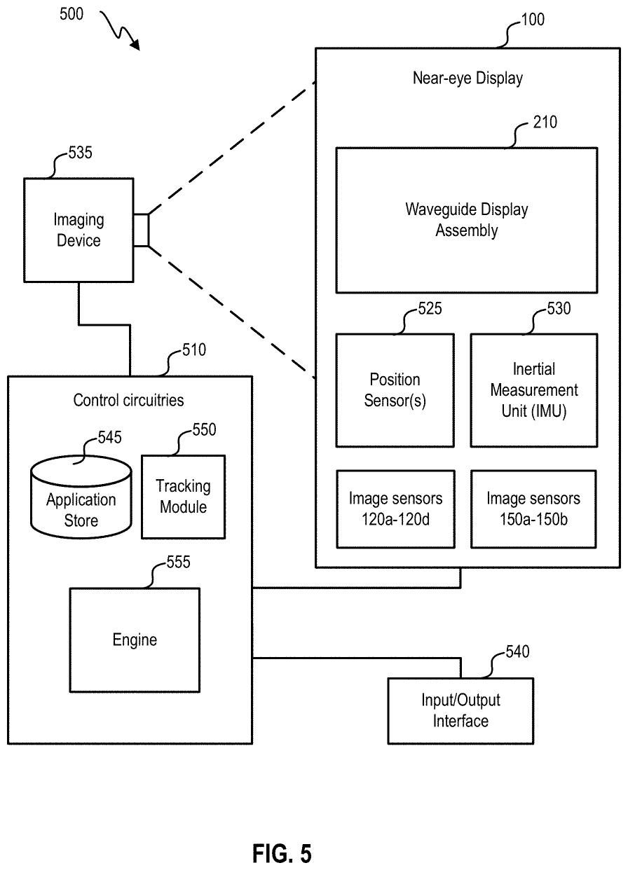

FIG. 5 is a block diagram of an embodiment of a system 500 including the near-eye display 100. The system 500 comprises near-eye display 100, an imaging device 535, an input/output interface 540, and image sensors 120a-120d and 150a-150b that are each coupled to control circuitries 510. System 500 can be configured as a head-mounted device, a mobile device, a wearable device, etc.

Near-eye display 100 is a display that presents media to a user. Examples of media presented by the near-eye display 100 include one or more images, video, and/or audio. In some embodiments, audio is presented via an external device (e.g., speakers and/or headphones) that receives audio information from near-eye display 100 and/or control circuitries 510 and presents audio data based on the audio information to a user. In some embodiments, near-eye display 100 may also act as an AR eyewear glass. In some embodiments, near-eye display 100 augments views of a physical, real-world environment, with computer-generated elements (e.g., images, video, sound).

Near-eye display 100 includes waveguide display assembly 210, one or more position sensors 525, and/or an inertial measurement unit (IMU) 530. Waveguide display assembly 210 includes source assembly 310, output waveguide 320, and controller 330.

IMU 530 is an electronic device that generates fast calibration data indicating an estimated position of near-eye display 100 relative to an initial position of near-eye display 100 based on measurement signals received from one or more of position sensors 525.

Imaging device 535 may generate image data for various applications. For example, imaging device 535 may generate image data to provide slow calibration data in accordance with calibration parameters received from control circuitries 510. Imaging device 535 may include, for example, image sensors 120a-120d of FIG. 1A for generating image data of a physical environment in which the user is located for performing location tracking of the user. Imaging device 535 may further include, for example, image sensors 150a-150b of FIG. 1B for generating image data for determining a gaze point of the user to identify an object of interest of the user.

The input/output interface 540 is a device that allows a user to send action requests to the control circuitries 510. An action request is a request to perform a particular action. For example, an action request may be to start or end an application or to perform a particular action within the application.

Control circuitries 510 provide media to near-eye display 100 for presentation to the user in accordance with information received from one or more of: imaging device 535, near-eye display 100, and input/output interface 540. In some examples, control circuitries 510 can be housed within system 500 configured as a head-mounted device. In some examples, control circuitries 510 can be a standalone console device communicatively coupled with other components of system 500. In the example shown in FIG. 5, control circuitries 510 include an application store 545, a tracking module 550, and an engine 555.

The application store 545 stores one or more applications for execution by the control circuitries 510. An application is a group of instructions that, when executed by a processor, generates content for presentation to the user. Examples of applications include: gaming applications, conferencing applications, video playback applications, or other suitable applications.

Tracking module 550 calibrates system 500 using one or more calibration parameters and may adjust one or more calibration parameters to reduce error in determination of the position of the near-eye display 100.

Tracking module 550 tracks movements of near-eye display 100 using slow calibration information from the imaging device 535. Tracking module 550 also determines positions of a reference point of near-eye display 100 using position information from the fast calibration information.

Engine 555 executes applications within system 500 and receives position information, acceleration information, velocity information, and/or predicted future positions of near-eye display 100 from tracking module 550. In some embodiments, information received by engine 555 may be used for producing a signal (e.g., display instructions) to waveguide display assembly 210 that determines a type of content presented to the user. For example, to provide an interactive experience, engine 555 may determine the content to be presented to the user based on a location of the user (e.g., provided by tracking module 550), or a gaze point of the user (e.g., based on image data provided by imaging device 535), a distance between an object and user (e.g., based on image data provided by imaging device 535).

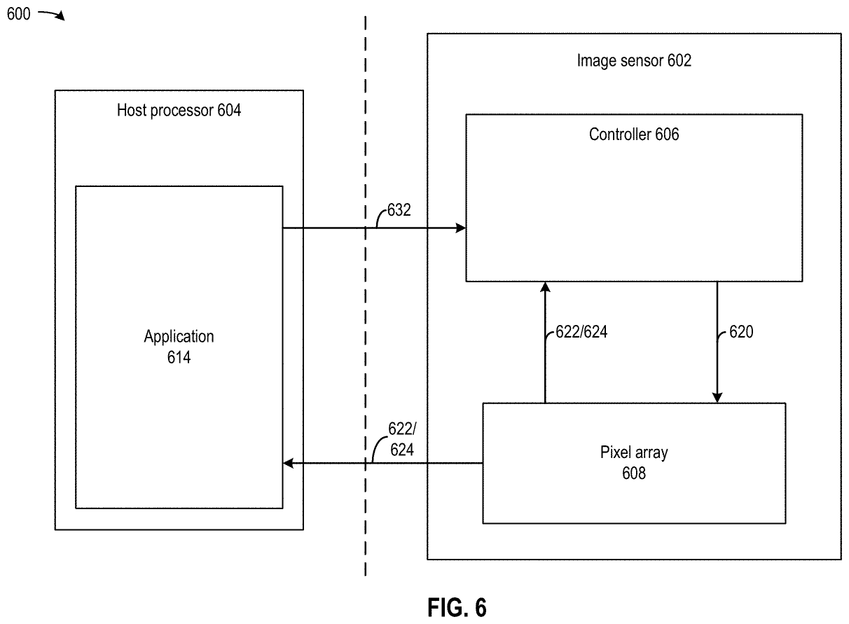

FIG. 6 illustrates an example of an imaging system 600 that can perform image sub-sampling with a color grid array. As shown in FIG. 6, imaging system 600 includes an image sensor 602 and a host processor 604. Image sensor 602 includes a controller 606 and a pixel array 608. In some examples, controller 606 can be implemented as an application specific integrated circuit (ASIC), a field programmable gate array (FPGA), or a hardware processor that executes instructions to enable image sub-sampling with a color grid array. In addition, host processor 604 includes a general purpose central processing unit (CPU) which can execute an application 614.

Each pixel of pixel array 608 receives incoming light and converts it into an electric charge, which is stored as a voltage on a charge storage device. In addition, each pixel in the pixel array 608 is individually addressable using row and column select lines, which cause corresponding row- and column-select switches to close, thereby providing a voltage to ADC circuitry from the pixel where it is converted into a pixel value which can be read out, such as to controller 606 or application 614.

In the pixel array 608, pixels are grouped together to form super-pixels, which provide common ADC circuitry for the grouped pixels. For example, a super-pixel may include four pixels arranged in a 2×2 grid. Thus, a 128×128 pixel array using such a configuration would create a 64×64 super-pixel array. To provide different color or frequency sensing, the different pixels within a super-pixel may be configured with different filters, such as to capture different visible color bands (e.g., red, green, blue, yellow, white), different spectral bands (e.g., near-infrared (“IR”), monochrome, ultraviolet (“UV”), IR cut, IR band pass), or similar. Thus, by enabling or disabling different pixels, each super-pixel can provide any subset of such information. Further, by only sampling certain super pixels, sparse image sensing can be employed to only capture image information corresponding to a subset of pixels in the pixel array 608.

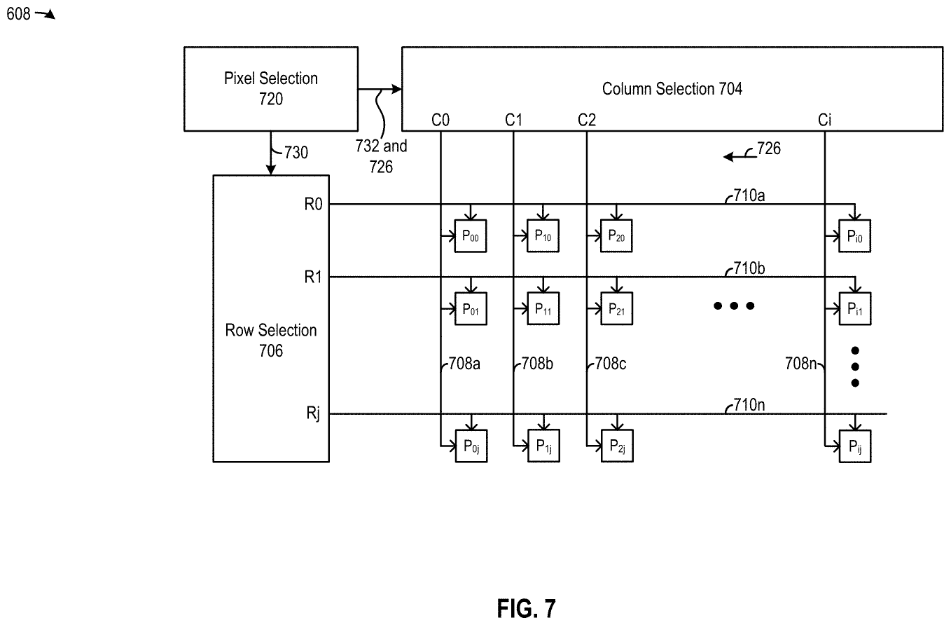

FIG. 7 illustrates an example of pixel array 608. As shown in FIG. 7, pixel cell array 608 may include a column controller 704, a row controller 706, and a pixel selection controller 720. Column selection controller 704 is connected with column-select lines 708 (e.g., 708a, 708b, 708c, . . . 708n), whereas row selection controller 706 is connected with row-select lines 710 (e.g., 710a, 710b, . . . 708n). Each box labelled P00, P01, P0j, . . . , Pij represents a pixel. Each pixel is connected to one of column-select lines 708, one of row-select lines 710 and an output data bus to output pixel data (not shown in FIG. 7). Each pixel is individually addressable by column-enable signals 730 on column-select lines 708 provided by column selection controller 704, and row-enable signals 732 on row-select lines 710 provided by row selection controller 706. Column-enable signals 730 and row-enable signals 732 can be generated based on information received from controller 606 or host processor 604.

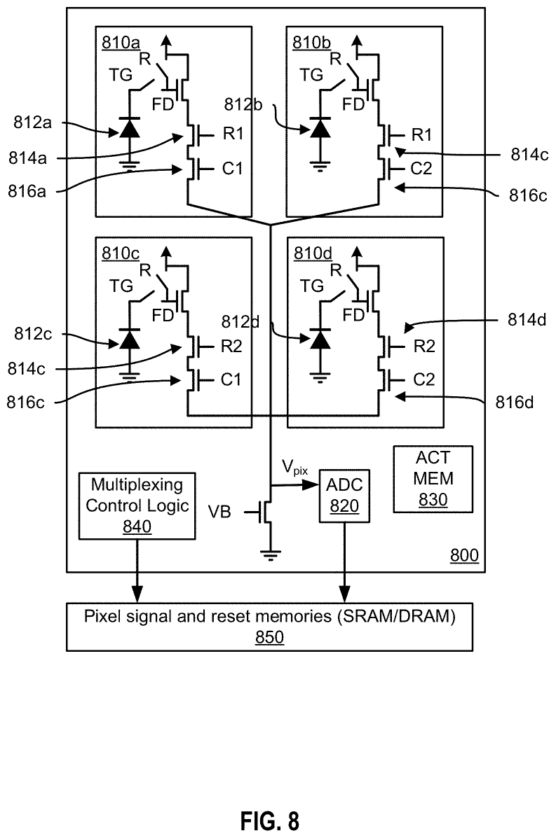

FIG. 8 illustrates an example super-pixel 800, which has four pixels 810a-d arranged in a 2×2 grid, though any suitable grouping of pixels into super-pixels may be used (e.g., 3×3, 4×1). Each pixel 810a-d includes a light-sensing element 812a-d, which in this example is a photodiode. The light-sensing elements 812a-d are each connected to a charge storage device, which in this example is a floating diffusion (“FD”) region. During an exposure period, the light-sensing elements 812a-d receive incoming light and generate electric charge, which is stored on the corresponding charge storage device as a voltage.

Each pixel 810a-d also includes a row-select switch 814a-d and a column-select switch 816a-d. The row- and column-select switches 814a-d, 816a-d are connected to the row-enable and column-enable lines R1-j, C1-Ci shown in FIG. 7. In this example, the four pixels are connected to different combinations of row-enable lines R1 and R2 and column-enable lines C1 and C2, resulting in different pixels transferring voltage to the ADC 820 depending on which particular lines are enabled.

The row- and column-switches are arranged in series to prevent transfer of voltage from the charge storage device unless both the corresponding row- and column-enable lines are enabled. For example, if R1 and C1 are both enabled, but R2 and C2 are disabled, pixel 810a will transfer its voltage to the ADC 820. However, none of the other pixels 810b-d will be able to since at least one switch will be open in each pixel.

It should be appreciated that while the row- and column-select switches 814a-d, 816a-d are connected between the charge storage device and the ADC 820, in some examples, one or both switches may be connected between the light-sensing element 812a-d and the corresponding charge storage device, or any other arrangement in which a signal is prevented from travelling from a particular pixel to the ADC unless both the row- and column-select switches for that pixel are closed. In addition, it should be appreciated that other components may be integrated within a pixel, such as an anti-blooming transistor.

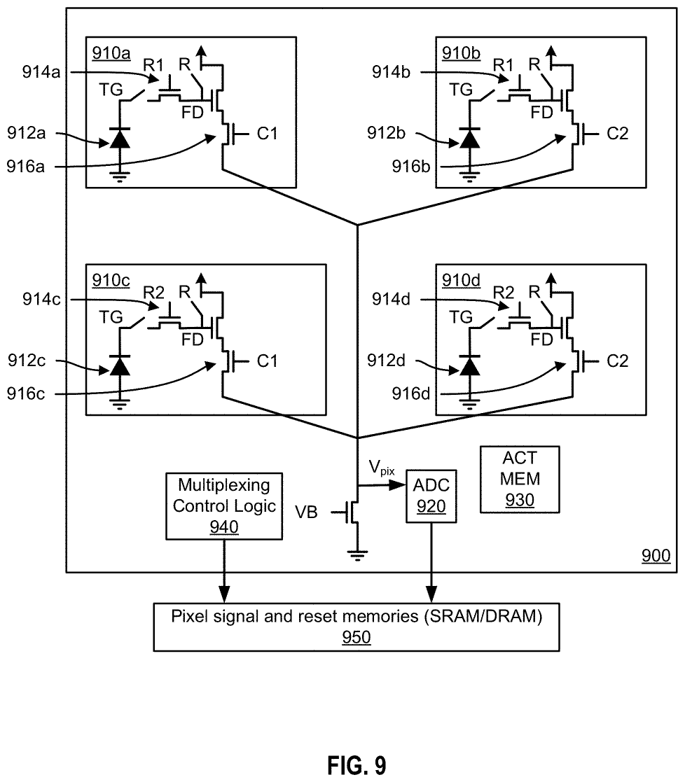

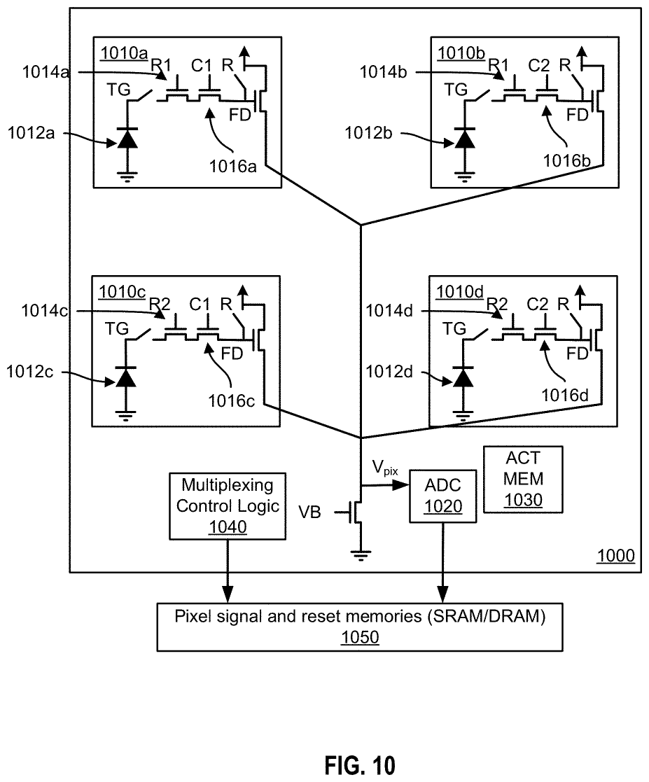

For example, FIG. 9 shows an example super-pixel 900 in which the pixels 910a-d have a row-select switch 914a-d positioned between the light-sensing element 912a-d and the charge storage device, and a column-select switch 916a-d positioned between the charge storage device and the ADC 920. Though in some examples the row-select switches 914a-d and the column-select switches 916a-d could be swapped so that the column-select switches 916a-d are positioned between the respective light-sensing element 912a-d and the charge storage device, and the row-select switches 914a-d are positioned between the respective charge storage device and the ADC 920. FIG. 10 shows another configuration where both the row- and column-select switches 1014a-d, 1016a-d are positioned between the respective light-sensing element 1012a-d and the respective charge storage device.

Referring again to FIG. 8, in addition to the pixels 810a-d, the super-pixel includes an ADC 820, an activation memory 830, and a multiplexing control 840 logic. The ADC 820 is connected to each of the pixels 810a-d to receive a voltage, Vₚᵢₓ, from a pixel that has both of its row- and column-select switches 814a-d, 816a-d closed. It converts the voltage to a pixel value, which is then stored in memory 850. Because the ADC 820 is writing up to four different pixel values to memory, each must be stored in a different location. Thus, the multiplexing control logic 840 ensures that each pixel value from a super pixel is stored in a memory location corresponding to the pixel. Further, configuration information to indicate how many pixels will be converted, which may be used to activate the ADC 820 for only the pixels to be sampled, as well as which pixel(s) may be activated, such as to select specific color channels per super-pixel or to enable functionality such as sparse sampling or foveated sampling, is stored in the activation memory 830.

After the ADC 820 has converted a pixel's value, the input voltage is reset by opening one or both of the respective pixel's row- and column-select switches. The row- and column-enable lines for the next pixel to be read may then be enabled. By stepping through some or all of the pixels in sequence, discrete pixel values may be output despite using only a single ADC for the super-pixel. However, power advantages may accrue in use cases when fewer than all the pixels have their values read.

Further, areal density may be improved by forming portions of the pixel on one layer of a substrate and other portions on a second layer. For example, a first layer of the substrate may include the pixels, while a second layer may include the ADC 820, activation memory 830, multiplexing control logic 840, and the memory 850. By stacking different components in different substrate layers, pixel density may be increased.

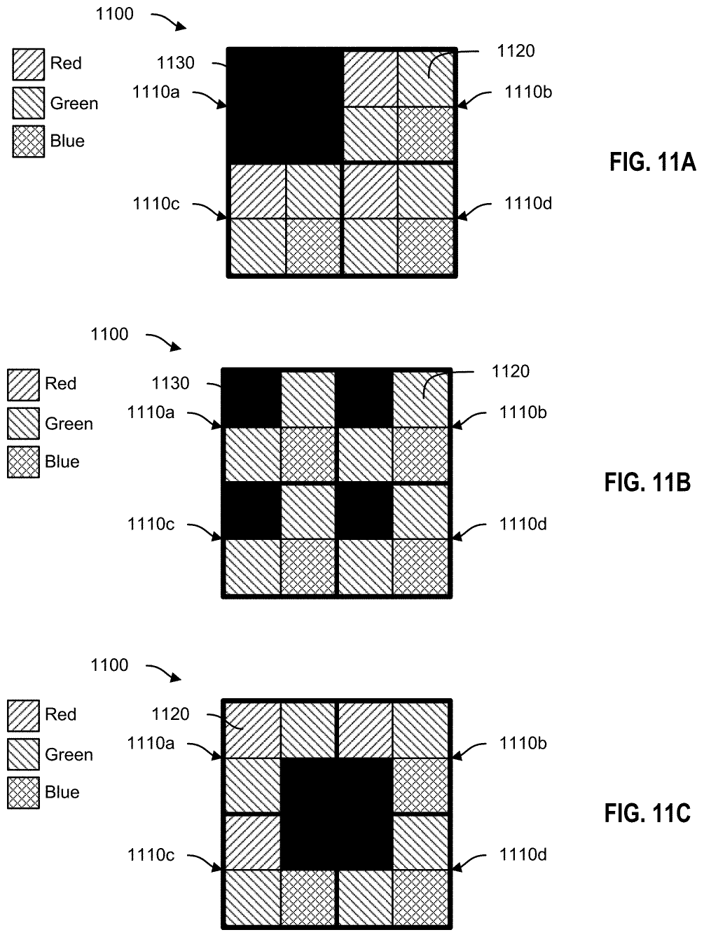

Referring to FIGS. 11A-C, FIG. 11A shows an example pixel array 1100 that includes four super-pixels 1110a-d arranged in a 2×2 grid. Each super-pixel 1110a-d includes four pixels 1120 arranged in a 2×2 grid. Each super-pixel 1110a-d in this example is configured according to the example shown in FIG. 8; however, any other suitable super-pixel configuration can be employed. For example, super-pixels can be configured to employ pixel arrays of size 2×1, 4×1, 3×3, etc.

Each pixel 1120 in this example also includes a filter to filter incoming light. Each super-pixel 1110a-d has the same arrangement of pixels with filters providing red, green, green, and blue filtered pixels as shown. By selectively sampling different combinations of pixels during any particular frame period, different kinds of pixel information can be captured by the image array 1100.

In this example, all pixels 1120 in each super-pixel 1110a-d are sampled and converted to pixel values, which is indicated by all of the pixels in super-pixel 1110a being shaded a darker color. To generate such an image, corresponding row- and column-enable lines are enabled in sequence for each pixel to close the corresponding row- and column-select switches, thus sampling the corresponding pixel voltage and generating a pixel value.

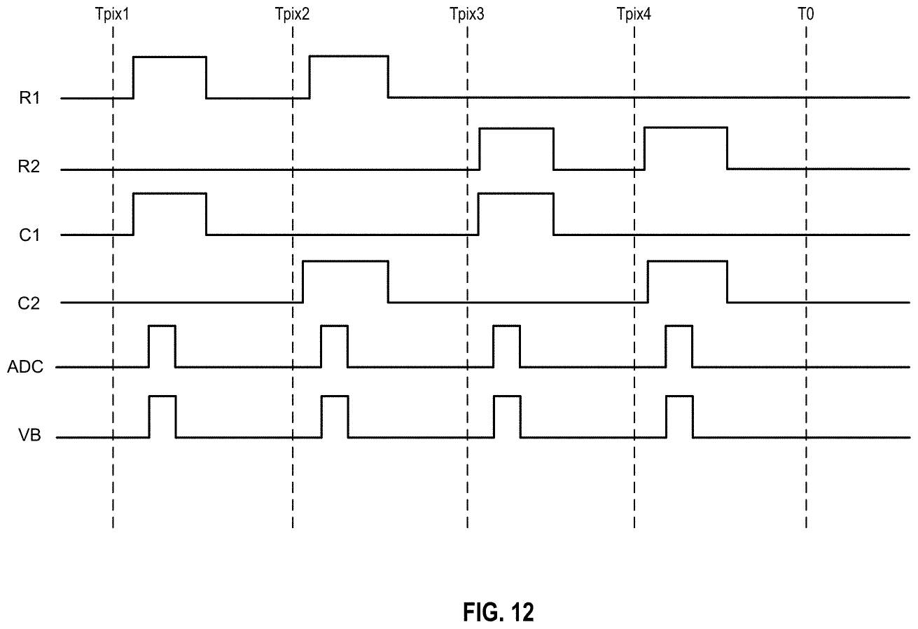

FIG. 12 shows a timing diagram 1200 for the super-pixel shown in FIG. 8 to capture all pixel values for the super-pixel 800. Such a technique could be used to generate a full-color, full-resolution image if the super-pixel is configured with the filter arrangement shown in FIG. 11A. The timing diagram 1200 begins at Tpix1, which occurs after the exposure period for the pixels has completed. At Tpix1, R1 and C1 are asserted to close corresponding row- and column-select switches. However, only pixel 810a has both of its row- and column-select switches closed. Thus, pixel 810a's voltage is presented to the ADC as Vpix. Subsequently, the ADC 820 and VB are enabled and the ADC 820 converts the voltage to a pixel value, which is stored in memory 850. Finally, R1 and C1 are de-asserted.

At Tpix2, R1 and C2 are asserted, which presents the voltage from pixel 810b to the ADC where it is converted to a pixel value according to the same process as for pixel 810a. Pixels 810c-d are then converted in sequence by asserting the corresponding row- and column-enable lines and converting their respective voltages. Such a configuration provides full-color pixel values (having red, green, and blue color channels) for each super pixel, thereby generating a full-resolution, full-color image. However, such comprehensive pixel information may not be needed in all examples.

For example, referring to FIG. 11B, the same pixel array 1100 has been configured to sample and convert pixel values only from pixels with red filters. Thus, row- and column-enable lines corresponding to pixels with red filters have been sampled, but no others. Thus, a full-resolution image is captured, but with only partial color channel information. Such a configuration may enable certain CV functionality to generate usable results, without the power overhead of capturing a full-color image.

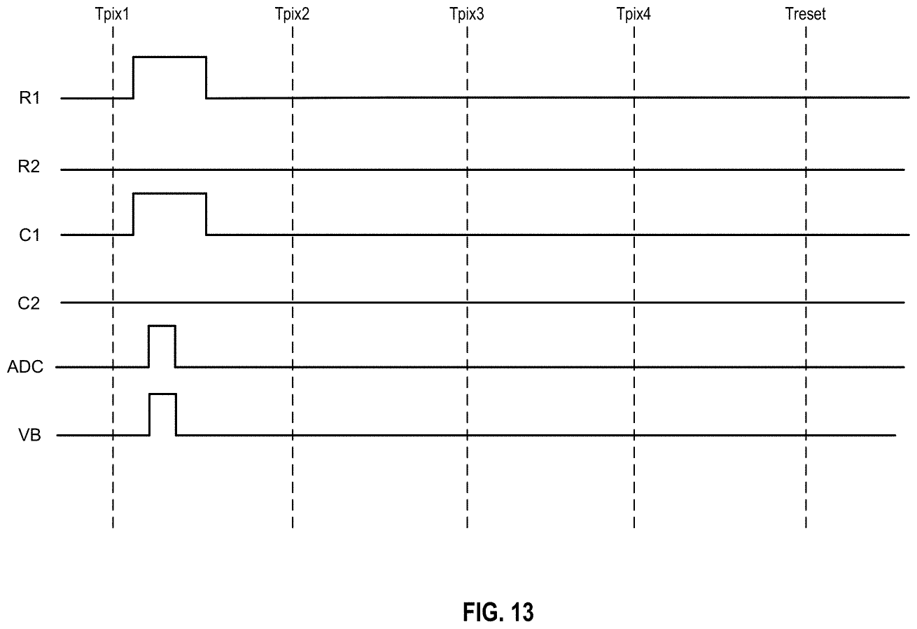

FIG. 13 illustrates a timing diagram 1300 to capture the red-channel pixels in one of the super-pixels 1110a, which can be applied to other pixels in the pixel array 608 to achieve a partial-color (e.g., red), full-resolution image. Because only one pixel value is converted, the R1 and C1 lines are asserted and the pixel's voltage is converted to a pixel value as described above with respect to FIG. 12. However, because no other pixels are being read, no more ADC operations occur, substantially reducing power consumption.

FIG. 11C shows a further configuration of the pixel array 1100. In this example, a full-color image is captured; however, because different color channels are provided by different super-pixels, the resulting image is not full resolution. Thus, each super-pixel 1110a-d contributes one pixel value, resulting in a single ADC operation per super-pixel. As a result substantial power savings can be realized, And while, the captured image is downsampled by a factor of four from the full-resolution of the pixel array, such a downsampled image may be useful for certain CV functionality, such as object tracking.

It should be appreciated that while the super-pixels 1110a-d shown in these examples provide RGGB color channels, any suitable combination of filters may be used according to different examples. For example, one of the green filters may be replaced by an IR filter or a UV filter. In some examples, entirely different sets of filters may be employed, e.g., white, yellow, IR, UV, etc. Thus, the number of pixels, the corresponding filters, and the pixel's arrangement within a super-pixels may be in any suitable configuration for a particular application.

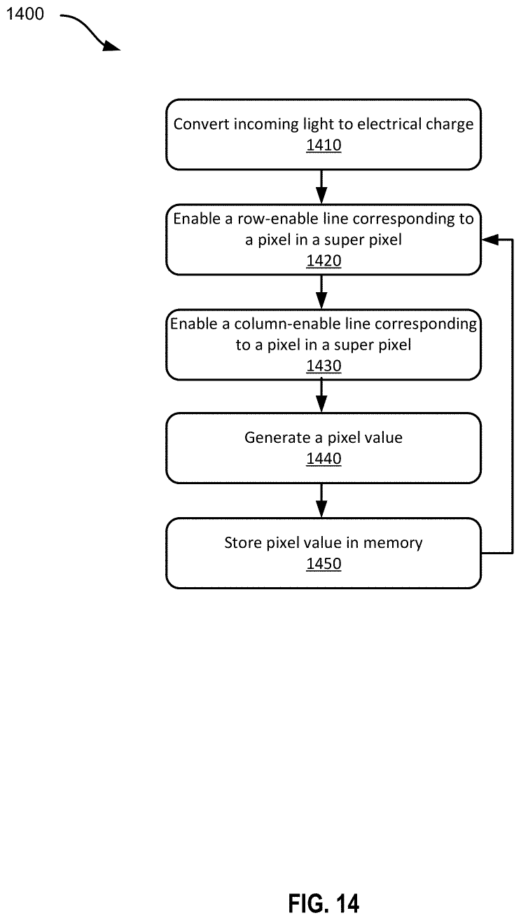

Referring now to FIG. 14, FIG. 14 shows a method 1400 for image sub-sampling with a color grid array. The example method 1400 will be described with respect to the image sensor 602 shown in FIGS. 6-7, the super-pixel shown in FIG. 8, and the filter arrangement shown in FIGS. 11A-C; however, it should be appreciated that any suitable super-pixel or filter arrangement may be employed.

At block 1410, each pixel 810a in the super-pixel 800 uses a photodiode to receive incoming light and convert it into electric charges during an exposure period. In this example, the electric charges are stored in a charge storage device, such as a floating diffusion. However, any suitable charge storage device may be employed. Further, in some examples, the electric charge may accumulate at the photodiode before later being connected to a discrete charge storage device, such as by one or more switches being closed to connect the photodiode to the charge storage device, such as illustrated in FIGS. 9-10.

At block 1420, the image sensor enables one or more row-select lines 706, e.g., R₀-Rⱼ. As discussed above with respect to FIG. 7, the row-select lines 706 are connected to pixels located in the corresponding row of the pixel array 602. When a row-select line is enabled, e.g., R0, row-select switches in the corresponding pixels are closed. This provides a part of an electrical pathway between the pixel and the ADC 820. However, as discussed above, the row-select switches 814a-d may be positioned between a charge storage device and the ADC 820, or between a photodiode 812a and the charge storage device. Thus a particular row-select switch may enable (at least in part) transfer of charge from the photodiode to the charge storage device, or transfer of a voltage from the charge storage device to the ADC 820, depending on the pixel configuration.

At block 1430, the image sensor enables one or more column-select lines 704, e.g., C₀-Cᵢ. Similar to the row-select lines, each of the column-select lines 704 is connected to pixels located in the corresponding column of the pixel array 602. When a column-select line is enabled, e.g., C0, column-select switches in the corresponding pixels are closed. This provides another part of the electrical pathway between the pixel and the ADC 820. However, as discussed above, the column-select switches 816a-d may be positioned between a charge storage device and the ADC 820, or between a photodiode 812a and the charge storage device. Thus a particular column-select switch may enable (at least in part) transfer of charge from the photodiode to the charge storage device, or transfer of a voltage from the charge storage device to the ADC 820, depending on the pixel configuration.

At block 1440, the ADC 820 generates a pixel value for each pixel of the super-pixel having both a row-select switch and a column-select switched closed. As discussed above with respect to FIG. 8, if only one of a pixel's row-select or column-select switches is closed, no electrical pathway from the pixel 810a-d to the ADC 820 is established. Thus, no pixel value can be determined for the pixel. However, because each pixel in a super-pixel has row- and column-select switches 814a-d, 816a-d, connected to different combinations of row- and column-select lines 704, 706, each pixel can be individually connected to the ADC 820 to have its voltage converted to a pixel value.

At block 1450, the pixel value is stored in memory 850.

Because each super-pixel 800 has more than one pixel, blocks 1420-1450 may be repeated for additional pixels in a super-pixel depending on whether additional combinations of row- and column-select lines 704, 706 are enabled in sequence. For example, as discussed above with respect to FIG. 12, different combinations of row- and column-select lines R1-R2, C1-C2 are enabled at different times, Tₚᵢₓ₁-Tₚᵢₓ₄, to generate pixel values for each pixel 810a-d in the super-pixel 800. However, as discussed with respect to FIGS. 11A-11C, only a subset of pixels per super-pixel may be used to generate pixel values. For example, FIG. 11B illustrates an example in which only pixels having red color filters are used to generate pixel values. To obtain those pixels, a row-select line for the top row of pixels for each super-pixel may be enabled, while the column-select line for the left column of pixels for each super-pixel may be substantially simultaneously enabled. Such a configuration enables one pixel per super-pixel corresponding to the red color filter.

Alternatively, different super-pixels may have different subsets of pixels selected for a particular image. For example, FIG. 11C illustrates an example where different pixels within adjacent super-pixels are enabled to capture a full-color image with reduced resolution. Thus, all pixels needed for the images captured by the configurations illustrated in FIGS. 11B-11C may be generated using a single pixel per super-pixel, meaning only a single ADC operation is needed per super-pixel. In contrast, the configuration in FIG. 11A requires four ADC operations for the super-pixel 1130.

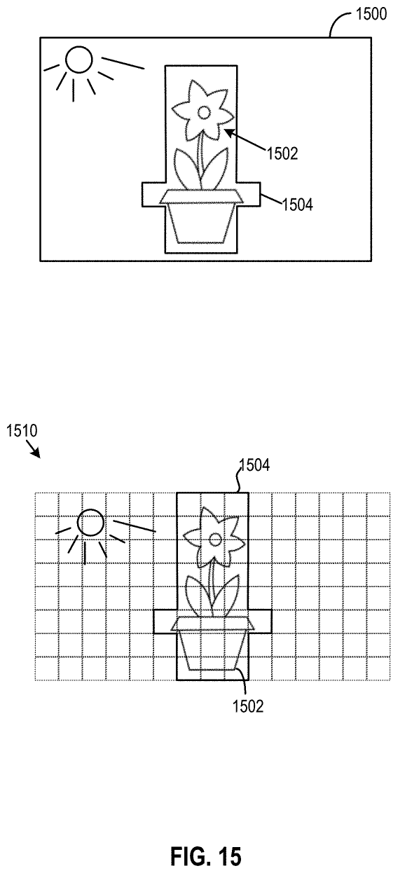

While these examples illustrate capturing repeating patterns of pixels within the pixel array, in some examples, only a subset of super-pixels within the pixel array 602 may be used to generate an image, referred to as “sparse” image sensing. For example, referring to FIG. 15, FIG. 15 shows a scene 1500 that includes an object 1502 of interest. Rather than capturing an image using every super-pixel 800 in a pixel array 608, the image sensor 602 may only use super-pixels corresponding to locations on the pixel array 608 that will receive light from the object. The image sensor 602 may have determined which super-pixels to use from a prior captured image, e.g., a full-resolution image captured using a reduced subset of pixels per super-pixel.

To only use the super-pixels 800 corresponding to the object 1502, the image sensor 602 may only enable row- and column-select lines 704, 706 corresponding to individual pixels within the set 1504 of super-pixels that are expected to receive light from the object 1502. Thus, rather than enabling all row- and column-select lines 704, 706, only a subset of those lines may be enabled. Further, the image sensor 602 may also determine whether to capture a full-color, sparse image or a partial color, sparse image. Depending on the selection, the image sensor 602 may enable some or all of the pixels within each of the super-pixels in the set 1504 of super-pixels. Thus, the image sensor 602 may selectively capture only the specific pixel information needed to accommodate other processing within the image sensor 602 or by a device connected to the image sensor 602.

The foregoing description of some examples has been presented only for the purpose of illustration and description and is not intended to be exhaustive or to limit the disclosure to the precise forms disclosed. Numerous modifications and adaptations thereof will be apparent to those skilled in the art without departing from the spirit and scope of the disclosure.

Reference herein to an example or implementation means that a particular feature, structure, operation, or other characteristic described in connection with the example may be included in at least one implementation of the disclosure. The disclosure is not restricted to the particular examples or implementations described as such. The appearance of the phrases “in one example,” “in an example,” “in one implementation,” or “in an implementation,” or variations of the same in various places in the specification does not necessarily refer to the same example or implementation. Any particular feature, structure, operation, or other characteristic described in this specification in relation to one example or implementation may be combined with other features, structures, operations, or other characteristics described in respect of any other example or implementation.

Use herein of the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A and B and C.

That which is claimed is:

1. A sensor apparatus comprising:
a super-pixel comprising an array of pixels, each pixel comprising a photodiode configured to generate a charge in response to incoming light, a filter positioned to filter the incoming light, a charge storage device to convert the charge to a voltage, a row-select switch, and a column-select switch;
an analog-to-digital converter (“ADC”) connected to each of the charge storage devices of the super-pixel via the respective row-select and column-select switches and configured to selectively convert each respective stored voltage into a pixel value in response to a control signal; and
wherein each row-select and column-select switch for a pixel is configured to selectively allow the charge or the voltage to propagate to the respective ADC, the row-select and column-select switches arranged in series.

2. The sensor apparatus of claim 1, wherein each pixel has a different filter from the other pixels in the array.

3. The sensor apparatus of claim 1, wherein the filters of the array of pixels include one or more of a red filter, a green filter, a blue filter, an infra-red filter, or an ultraviolet filter.

4. The sensor apparatus of claim 1, further comprising a plurality of super-pixels arranged in an array.

5. The sensor apparatus of claim 4, wherein each super-pixel includes a 2×2 array of pixels.

6. The sensor apparatus of claim 4, further comprising a pixel configuration controller configured to:
receive pixel control information for one or more super-pixels;
selectively control row-select and column-select switches for each of the one or more super-pixels; and
transmit the control signal to each of the super-pixels.

7. The sensor apparatus of claim 1, wherein, for each pixel, at least one of the row-select switch or column-select switch is connected between the photodiode and the charge storage device.

8. The sensor apparatus of claim 1, wherein, for each pixel, at least one of the row-select switch or column-select switch is connected between the charge storage device and the ADC.

9. The sensor apparatus of claim 1, further comprising, for each pixel, an anti-blooming transistor.

10. The sensor apparatus of claim 1, wherein the pixels are formed in a first layer of a semiconductor substrate and the ADC is formed in a second layer of the semiconductor substrate.

11. A sensor apparatus comprising:
an array of super-pixels arranged in rows and columns, each super-pixel of the array of super-pixels comprising an array of pixels arranged in rows and columns and an analog-to-digital converter (ADC) connected to each pixel,
each pixel comprising a photodiode configured to generate a charge in response to incoming light, a filter positioned to filter the incoming light, a charge storage device to convert the charge to a voltage, a row-select switch, and a column-select switch, wherein each row-select and column-select switch for a pixel is configured to selectively allow the charge or the voltage to propagate to the respective ADC, the row-select and column-select switches arranged in series;
a plurality of row-select lines, each row-select line corresponding to a row of pixels within a row of super-pixels in the array of super-pixels, each row-select line connected to row-select switches of the pixels within the respective row of pixels;
a plurality of column-select lines, each column-select line corresponding to a column of pixels within a column of super-pixels in the array of super-pixels, each column-select line connected to column -select switches of the pixels within the respective column of pixels; and
a plurality of ADC enable lines, each ADC enable line configured to provide a control signal to enable at least one ADC.

12. The sensor apparatus of claim 11, wherein each pixel array comprises four pixels arranged in a 2×2 array.

13. The sensor apparatus of claim 12, wherein a first filter of each pixel array comprises a red filter, a second filter of each pixel array comprises a green filter, and a third filter of each pixel array comprises a blue filter.

14. The sensor apparatus of claim 11, wherein, for each pixel, at least one of the row-select switch or column-select switch is connected between the photodiode and the charge storage device.

15. The sensor apparatus of claim 11, wherein, for each pixel, at least one of the row-select switch or column-select switch is connected between the charge storage device and the respective ADC.

16. The sensor apparatus of claim 11, further comprising, for each pixel, an anti-blooming transistor.

17. The sensor apparatus of claim 11, wherein the pixels of each super-pixel are formed in a first layer of a semiconductor substrate and the ADC of each super-pixel is formed in a second layer of the semiconductor substrate.

18. A method performed using a sensor apparatus comprising an array of super-pixels, each super-pixel comprising a plurality of pixels and being connected to an analog-to-digital converter (ADC), wherein each pixel for a super-pixel has a corresponding row-select switch and column-select switch, arranged in series, to allow a signal to propagate to the ADC when both switches are enabled, the method comprising:
converting, by photodiodes of the pixels, incoming light in to electric charge;
enabling a first row-select line, the first row-select line coupled to row-select switches in a first set of pixels in a first set of super-pixels of the array of super-pixels;
enabling a first column-select line, the first column-select line coupled to column-select switches in a second set of pixels in a second set of super-pixels of the array of super-pixels; and
generating, using the ADC corresponding to a super-pixel in both the first and second sets of super-pixels, a pixel value for each pixel of the respective super-pixel having both a row-select switch and column-select switch closed.

19. The method of claim 18, wherein each super-pixel comprises four pixels arranged in a 2×2 pixel array, and wherein a first filter of each 2×2 pixel array comprises a red filter, a second filter of each 2×2 pixel array comprises a green filter, and a third filter of each 2×2 pixel array comprises a blue filter, and the method further comprising:
enabling a plurality of row-select and column-select lines corresponding only to pixels having a first color filter.

20. The method of claim 18, wherein each super-pixel comprises four pixels arranged in a 2×2 pixel array, and wherein a first filter of each 2×2 pixel array comprises a red filter, a second filter of each 2×2 pixel array comprises a green filter, and a third filter of each 2×2 pixel array comprises a blue filter, and the method further comprising:
enabling a first plurality of row-select and column-select lines corresponding only to pixels having a red filter;
enabling a first plurality of row-select and column-select lines corresponding only to pixels having a green filter; and
enabling a first plurality of row-select and column-select lines corresponding only to pixels having a blue filter.
